(19) United States
(12) Patent Application Publication
(10) Pub. No.: US 2025/0279381 A1
(43) Pub. Date: Sep. 4, 2025

(54) SEMICONDUCTOR DIE HAVING A DIE LEVEL DISTRIBUTION (DLD) METALLIZATION STRUCTURE INCLUDING A METAL PAD AND A SHORTER VIA COUPLING THE METAL PAD TO A METAL INTERCONNECT IN THE DIE FOR IMPROVED SIGNAL PATH CONDUCTIVITY

(71) Applicant: QUALCOMM Incorporated, San Diego, CA (US)

(72) Inventors: Yangyang Sun, San Diego, CA (US); Xuefeng Zhang, San Diego, CA (US); Dongming He, San Diego, CA (US); Wei Hu, San Diego, CA (US)

(21) Appl. No.: 18/591,820

(22) Filed: Feb. 29, 2024

(51) Int. Cl. H01L 23/00; H01L 23/48; H01L 25/10

(52) U.S. Cl. CPC H01L 24/16; H01L 23/481; H01L 24/32; H01L 24/73; H01L 25/105; H01L 24/75; H01L 24/81; H01L 2224/16225; H01L 2224/32225; H01L 2224/73204; H01L 2224/75702; H01L 2224/81203; H01L 2224/81801; H01L 2924/1436

(57) ABSTRACT

Aspects disclosed in the detailed description include a semiconductor die having a die level distribution (DLD) metallization structure including a metal pad and a short via coupled to the metal pad to a metal interconnect in the die for improved signal path conductivity. The DLD metallization structure includes an outer metallization layer comprising the metal interconnect, a first passivation layer adjacent to the outer metallization layer and a DLD metallization layer adjacent to the first passivation layer. The DLD metallization layer comprises a first surface adjacent to the first passivation layer and a metal pad. The DLD metallization structure includes a first via extending in the second direction orthogonal to the first direction, the first via coupling the metal pad and the metal interconnect, the first via having a first aspect ratio between 0.06-0.5, inclusively.

### BACKGROUND

### I. Field of the Disclosure

The field of the disclosure relates to integrated circuit (IC) packages that include one or more semiconductor dies (“dies”) attached to a package substrate, and more particularly to a die level distribution (DLD) metallization structure on a die(s).

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

The die(s) also includes one or more metallization layers that include metal interconnects (e.g., metal traces, metal lines). The one or more metallization layers are fabricated in the die(s) utilizing a back end of line (BEOL) process. A die level distribution (DLD) metallization layer includes metal interconnects and metal pads. The DLD metallization layer couples to an outer metallization layer which includes metal interconnects fabricated during the BEOL process. The die(s) also includes die interconnects (e.g., balls or pillars) which are supported by metal pads in the DLD metallization layer and electrically couple the metal interconnects in the die(s) to the metal interconnects exposed in the outer metallization layer of the package substrate or another die.

### SUMMARY

Aspects disclosed in the detailed description include a semiconductor die having a die level distribution (DLD) metallization structure including a metal pad and a shorter via coupling the metal pad to a metal interconnect in the die for improved signal path conductivity. Related integrated circuit (IC) packages and fabrication methods are also disclosed. The die includes a semiconductor layer, a DLD metallization structure, and a back end of line (BEOL) interconnect structure between the semiconductor layer and the DLD metallization structure. The DLD metallization structure mechanically supports die interconnects for coupling the die to another device, such as a package substrate or another die, and redistributes signals (e.g., power, ground, information) between the die interconnects and the semiconductor layer through the BEOL interconnect structure.

In this regard, the DLD metallization structure includes a DLD metallization layer and a passivation layer disposed between the DLD metallization layer and an outer metallization layer in the BEOL interconnect structure, forming a diffusion barrier therebetween. Vias are formed in the passivation layer to couple metal pads in the DLD metallization layer to metal interconnects in a BEOL interconnect layer in the BEOL interconnect structure. It is desired to reduce the signal path resistance or, conversely, improve signal path conductivity between the die interconnects and the BEOL interconnect structure.

In this regard, in exemplary aspects, the passivation layer between the DLD metallization structure and the BEOL interconnect structure is provided as a thinner layer to minimize the distance between the DLD metallization structure and the BEOL interconnect structure. For example, the height or thickness of the passivation layer may be between 0.1 micrometer (μm) and 1 μm, inclusively, and is fabricated at this thin layer because the passivation layer's purpose is to merely act as a diffusion barrier.

In another exemplary aspect, a second passivation layer is provided between the DLD metallization structure and the die interconnects to act as a diffusion barrier between metal pads and traces in the DLD metallization structure. If the die is bonded to a package substrate as opposed to another die, for example, which requires a smooth coupling surface between dies, the second passivation layer can also be thinner. In a die-to-die bonding approach, a polishing step, such as a chemical mechanical polishing (CMP), is needed to fabricate the smooth coupling surface and requires a thick passivation layer to include margin material which is removed when performing the polishing step. Avoiding the polishing step enables the passivation layer to be formed as a thin layer since the passivation layer does not need to include margin material and advantageously simplifies the process of fabricating the die.

In this regard in one aspect, a semiconductor die (die), comprises a semiconductor layer extending in a first direction, a die level distribution (DLD) metallization structure and a back end of line (BEOL) interconnect structure between the semiconductor layer and the DLD metallization structure. The BEOL interconnect structure extending in a second direction orthogonal to the first direction. The DLD metallization structure comprises an outer metallization layer extending in the first direction, the outer metallization layer comprising a metal interconnect. The DLD metallization structure further comprises a first passivation layer extending in the first direction adjacent to the outer metallization layer and a DLD metallization layer extending in the first direction. The DLD metallization layer comprises a first surface adjacent to the first passivation layer and a metal pad. The DLD metallization structure further comprises a first via extending in the second direction orthogonal to the first direction, the first via coupling the metal pad and the metal interconnect, the first via having a first aspect ratio between 0.06-0.5, inclusively.

In another aspect, a method of fabricating a semiconductor die (die) for improved signal path conductivity, comprises fabricating a semiconductor layer extending in a first direction, fabricating a die level distribution (DLD) metallization structure, and fabricating a back end of line (BEOL) interconnect structure between the semiconductor layer and the DLD metallization structure, the BEOL interconnect structure extending in a second direction orthogonal to the first direction. Wherein fabricating the DLD metallization structure comprises fabricating an outer metallization layer extending in the first direction, the outer metallization layer comprising a metal interconnect, fabricating a first passivation layer extending in the first direction adjacent to the outer metallization layer, and fabricating a DLD metallization layer extending in the first direction. The DLD metallization layer comprises a first surface adjacent to the first passivation layer and a metal pad. The method of fabricating a semiconductor die further comprises fabricating a first via extending in the second direction orthogonal to the first direction, the first via coupling the metal pad and the metal interconnect, the first via having a first aspect ratio between 0.06-0.5, inclusively.

### BRIEF DESCRIPTION OF THE DRAWINGS

FIG. 1 is a side view of a die having a thick passivation layer below and above a die level distribution (DLD) metallization layer;

FIG. 2 is a cross-sectional side view of an exemplary integrated circuit (IC) package that includes a semiconductor die (“die”) having a DLD metallization structure including a metal pad and a shorter via coupling the metal pad to a metal interconnect in the die for improved signal path conductivity;

FIG. 3 is a side view of an IC that includes a die in the IC package of FIG. 2, the die including a DLD metallization structure including a metal pad and a shorter via coupling the metal pad to a metal interconnect in the die for improved signal path conductivity;

FIG. 4A is a side view of an embodiment of the die in FIG. 3 focusing on an exemplary DLD metallization structure which includes a metal pad and a shorter via coupling the metal pad to a metal interconnect in the die for improved signal path conductivity;

FIG. 4B is a side view of an exemplary IC package including the die in FIG. 4A rotated 180° and assembled to a substrate;

FIG. 4C is a side view of another embodiment of the die in FIG. 3 focusing on an exemplary DLD metallization structure which includes a metal pad and a shorter via coupling the metal pad to a metal interconnect in the die for improved signal path conductivity;

FIG. 4D is a side view of an exemplary IC package including the die in FIG. 4C rotated 180° and assembled to a substrate;

FIG. 4E is a side view of another embodiment of the die in FIG. 3 focusing on an exemplary DLD metallization structure which includes a metal pad and a shorter via coupling the metal pad to a metal interconnect in the die for improved signal path conductivity;

FIG. 4F is a side view of an exemplary IC package including the die in FIG. 4C rotated 180° and assembled to a substrate;

FIG. 5 is a flowchart illustrating an exemplary fabrication process of fabricating a DLD metallization structure including a metal pad and a shorter via coupling the metal pad to a metal interconnect in the die for improved signal path conductivity, including, but not limited to, the exemplary DLD metallization structures in FIGS. 3 and 4A-4F;

FIGS. 6A-6F is a flowchart illustrating another exemplary fabrication process of fabricating a DLD metallization structure including a metal pad and a shorter via coupling the metal pad to a metal interconnect in the die for improved signal path conductivity, including, but not limited to, the exemplary DLD metallization structures in FIGS. 3 and 4A-4F;

FIGS. 7A-7O1 and 7N2 are exemplary fabrication stages during fabrication of the DLD metallization structure according to the fabrication process in FIGS. 6A-6F;

FIGS. 8A-8B is a flowchart illustrating an exemplary mass reflow assembly process of assembling a die to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 4A-4F;

FIGS. 9A-9D are exemplary assembly stages for assembling the die to the substrate according to the assembly process in FIGS. 8A-8B;

FIGS. 10A-10B is a flowchart illustrating an exemplary thermal compression assembly process of assembling a die to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 4A-4F;

FIGS. 11A-11D are exemplary assembly stages during assembling the die to the substrate according to the assembly process in FIGS. 10A-10B;

FIG. 12 is a block diagram of an exemplary processor-based system that can include components deployed in an IC package employing a die(s) coupled to a package substrate, wherein the die(s) can include a DLD metallization structure including a metal pad and a shorter via coupling the metal pad to a metal interconnect in the die for improved signal path conductivity, including, but not limited to, the exemplary DLD metallization structures in FIGS. 3 and 4A-4F, according to the exemplary fabrication processes in FIG. 5 and FIGS. 6A-6F, and according to exemplary assembly processes in FIGS. 8A-8B and 10A-10B; and

FIG. 13 is a block diagram of an exemplary wireless communications device that includes radio-frequency (RF) components deployed in an IC package, wherein the IC package includes a DLD metallization structure including a metal pad and a shorter via coupling the metal pad to a metal interconnect in the die for improved signal path conductivity, including, but not limited to, the exemplary DLD metallization structures in FIGS. 3 and 4A-4F, according to the exemplary fabrication processes in FIG. 5 and FIGS. 6A-6F, and according to exemplary assembly processes in FIGS. 8A-8B and 10A-10B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise.

Aspects disclosed in the detailed description include a semiconductor die having a die level distribution (DLD) metallization structure including a metal pad and a shorter via coupling the metal pad to a metal interconnect in the die for improved signal path conductivity. Related integrated circuit (IC) packages and fabrication methods are also disclosed. The die includes a semiconductor layer, a DLD metallization structure, and a back end of line (BEOL) interconnect structure between the semiconductor layer and the DLD metallization structure. The DLD metallization structure mechanically supports die interconnects for coupling the die to another device, such as a package substrate or another die, and redistributes signals (e.g., power, ground, information) between the die interconnects and the semiconductor layer through the BEOL interconnect structure.

In this regard, the DLD metallization structure includes a DLD metallization layer and a passivation layer disposed between the DLD metallization layer and an outer metallization layer in the BEOL interconnect structure, forming a diffusion barrier therebetween. Vias are formed in the passivation layer to couple metal pads in the DLD metallization layer to metal interconnects in a BEOL interconnect layer in the BEOL interconnect structure. It is desired to reduce the signal path resistance or, conversely, improve signal path conductivity between the die interconnects and the BEOL interconnect structure.

In this regard, in exemplary aspects, the passivation layer between the DLD metallization structure and the BEOL interconnect structure is provided as a thinner layer to minimize the distance between the DLD metallization structure and the BEOL interconnect structure. For example, the height or thickness of the passivation layer may be between 0.1 micrometer (μm) and 1 μm, inclusively, and is fabricated at this thin layer because the passivation layer's purpose is to merely act as a diffusion barrier.

In another exemplary aspect, a second passivation layer is provided between the DLD metallization structure and the die interconnects to act as a diffusion barrier between metal pads and traces in the DLD metallization structure. If the die is bonded to a package substrate as opposed to another die, for example, which requires a smooth coupling surface between dies, the second passivation layer can also be thinner. In a die-to-die bonding approach, a polishing step, such as a chemical mechanical polishing (CMP), is needed to fabricate the smooth coupling surface and requires a thick passivation layer to include margin material which is removed when performing the polishing step. Avoiding the polishing step enables the passivation layer to be formed as a thin layer since the passivation layer does not need to include margin material and advantageously simplifies the process of fabricating the die.

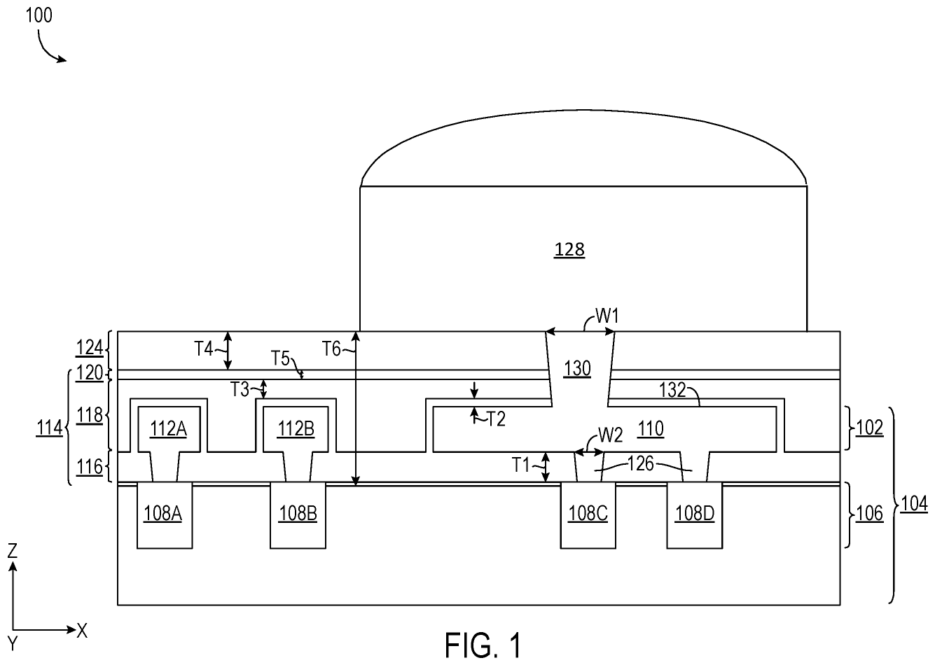

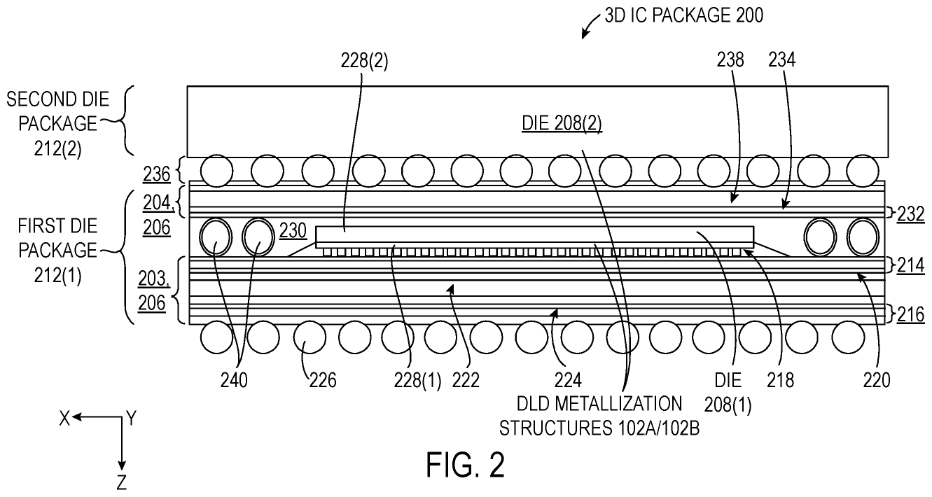

Before discussing exemplary aspects starting at FIG. 2, a conventional die having a thick passivation layer which surrounds a DLD metallization layer is first discussed with reference to FIG. 1. In this regard, FIG. 1 is a side view of a die 100 having a thick passivation layer below and above a DLD metallization layer 102. The die 100 includes a portion of a BEOL interconnect structure 104 which includes a stack of metallization layers illustrated only for simplicity as an outer metallization layer 106 and the DLD metallization layer 102. The outer metallization layer 106 includes metal interconnects 108A-108D. The DLD metallization layer 102 includes a metal pad 110 and metal traces 112A-112B. The die 100 includes a thick passivation layer 114 which surrounds the DLD metallization layer 102 which utilizes copper (Cu). The thick passivation layer 114 includes a first silicon nitride (SiN) layer 116 which extends in the vertical direction (Z-axis direction) above and below the metal traces 112A-112B and the metal pad 110 and provides a diffusion barrier to the Cu DLD metallization layer 102. The thickness T1 in the vertical direction (Z-axis direction) of the first SiN layer 116 below the metal traces 112A-112B and the metal pad 110 is approximately 2 micrometers (μm). The thickness T2 in the vertical direction (Z-axis direction) of the first SiN layer 116 above the metal traces 112A-112B and metal pad 110 is approximately 0.5 μm. The thick passivation layer 114 also includes a silicon dioxide (SiO₂) layer 118 between a second SiN layer 120 and the first SiN layer 116. The thickness T3 in the vertical direction (Z-axis direction) of the SiO₂ layer 118 between the second SiN layer 120 and the top surface of the first SiN layer 116 is approximately 4 μm. The thickness T5 in the vertical direction (Z-axis direction) of the second SiN layer 120 is approximately 0.7 μm. The die 100 also includes a polyimide layer 124 having a thickness T4 in the vertical direction (Z-axis direction) of approximately 4.5 μm. The total thickness T6 is approximately 11-15 μm.

The metal pad 110 is coupled to metal interconnects 108C and 108D by vias 126. The die 100 also includes an optional die interconnect 128 which is formed in a subsequent bumping process depending on what the die 100 will be coupled to such as a substrate or another die. The die interconnect 128 couples to the metal pad 110 through a via 130

The process in fabricating the die 100 utilizes foundry design rules to support subsequently bonding the die 100 to either a substrate or to another die. When bonding to another die in a die-die hybrid process, a top surface 132 of the metal pad 110 has to be smooth to couple to another die in a Cu to Cu hybrid bonding process. In such a process, the die interconnect 128 would not be illustrated. To smooth the top surface 132 of the metal pad 110, a polishing process such as a CMP process is used. When using a polishing process, the passivation layer 114 has to be thicker in order to provide margin material above the DLD metallization layer 102 which is worn away during the polishing process. Additionally, the die 100 utilizes the optional polyimide layer 124 as a hard etch material to pattern vias, such as the via 130, to metal pads, such as the metal pad 110 as opposed to using a separate photo resist which is removed after such patterning. Utilizing the polyimide layer 124 as a hard etch, some of the passivation layer 114 is compromised during the hard etching process so that additional margin material in the passivation layer 114 is required.

The thickness of the polyimide layer 124 and the thickness of the passivation layer 114 defines the height of the via 130. As a result, the height T2+T3+T4+T5 of the via 130 is approximately 9.7 μm and the width W1 of the via 130 is approximately 20-40 μm, resulting in an aspect ratio between 2.5 and 5. The thickness T1 of the passivation layer 114 defines the height of the vias 126. The die 100 may have been fabricated with some design rules when the DLD metallization layer 102 was made from aluminum and not copper and may be one reason why the first SiN layer 116 has the thickness T1. The height of the vias 126 in the vertical direction (Z-axis) is approximately 2 μm and a width W2 is between 1.67 μm and 4 μm yielding an aspect ratio (height/width) between 0.5 and 1.2.

If a die need not be assembled through a die-to-die hybrid process, a polishing process during fabrication of the die can be avoided, thus, a thinner passivation layer may result, and thus shorter via heights are advantageously achieved for vias between metal pads in the DLD metallization layer and metal interconnects in the outer metallization layer. Additionally, if an optional polyimide layer is used but, in doing so, a photo resist process is utilized to pattern vias to metal pads, shorter via heights are advantageously achieved for vias between die interconnects and metal pads. Shorter via heights are proportional to higher signal path conductivity.

In this regard, FIG. 2 is a cross-sectional side view of an exemplary IC package that includes a semiconductor die (“die”) having a DLD metallization structure including a metal pad and a shorter via coupling the metal pad to a metal interconnect in the die for improved signal path conductivity. In this example, the exemplary IC package is a three-dimensional (3D) IC (3DIC) package 200 that includes DLD metallization structures 202A-202B including a metal pad and a shorter via coupling the metal pad to a metal interconnect in the die for improved signal path conductivity. The IC package 200 includes a package substrate 203 and an interposer substrate 204. The package substrate 203 and the interposer substrate 204 commonly route signals and power and, for convenience, may both be referred to simply as a substrate 206.

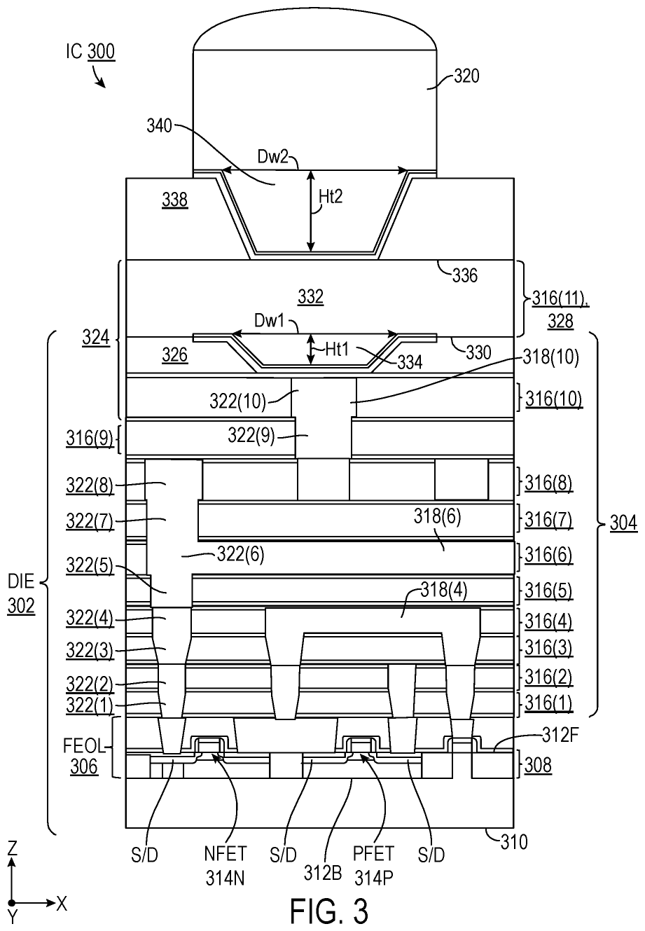

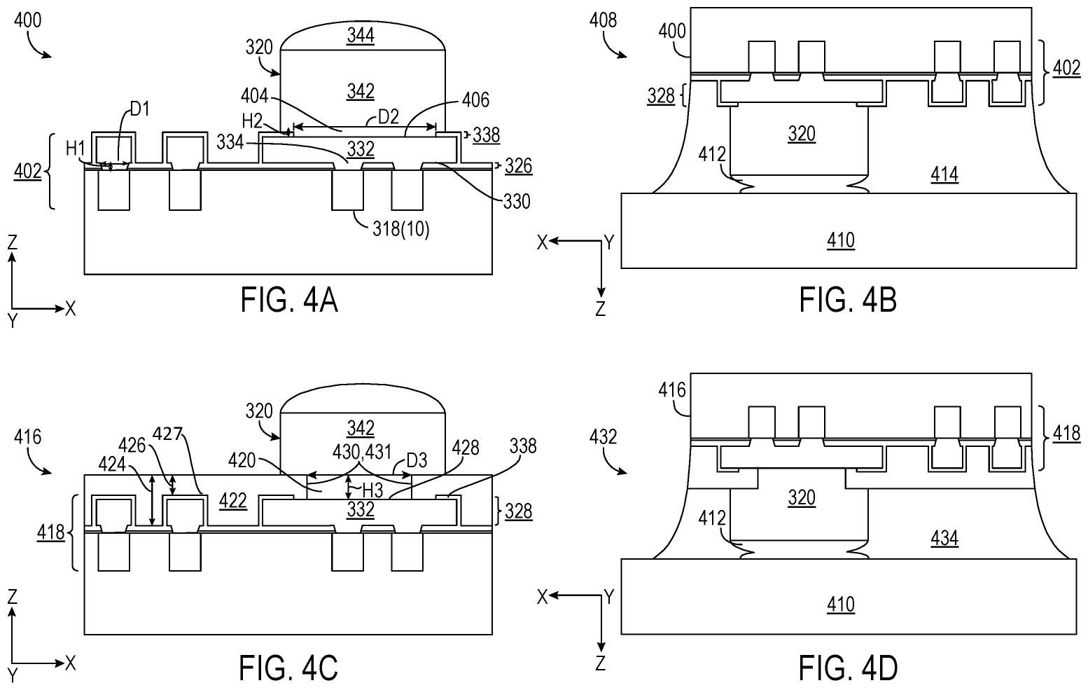

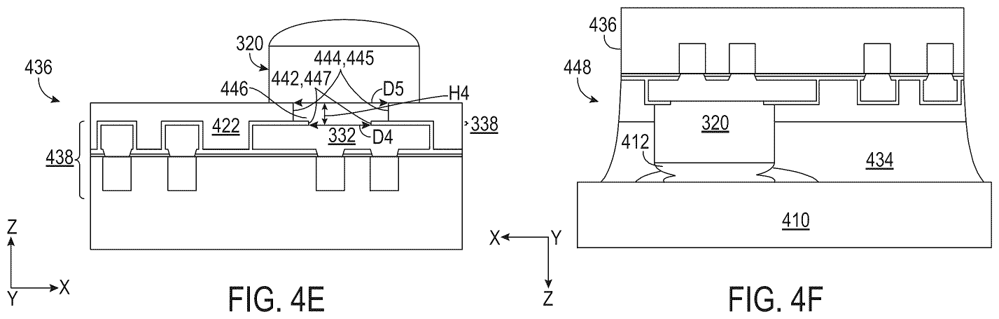

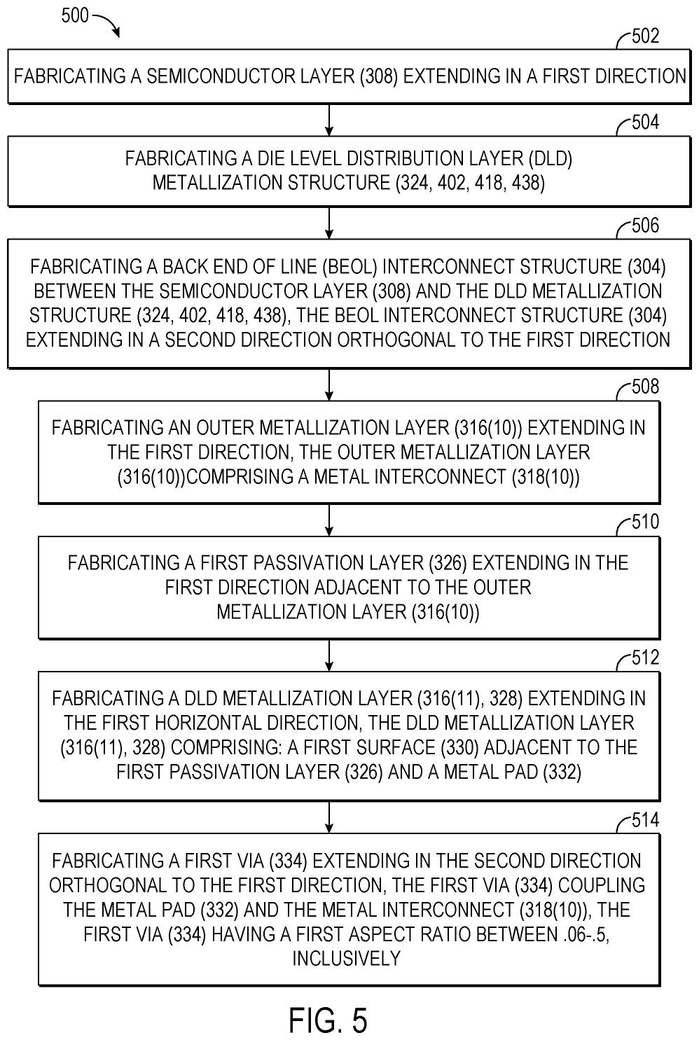

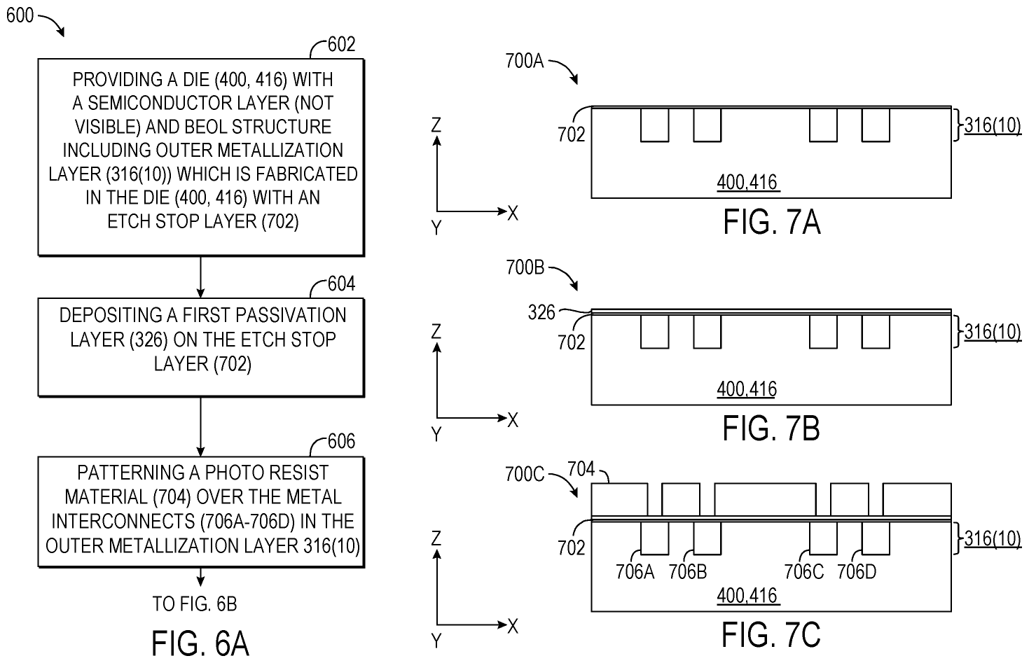

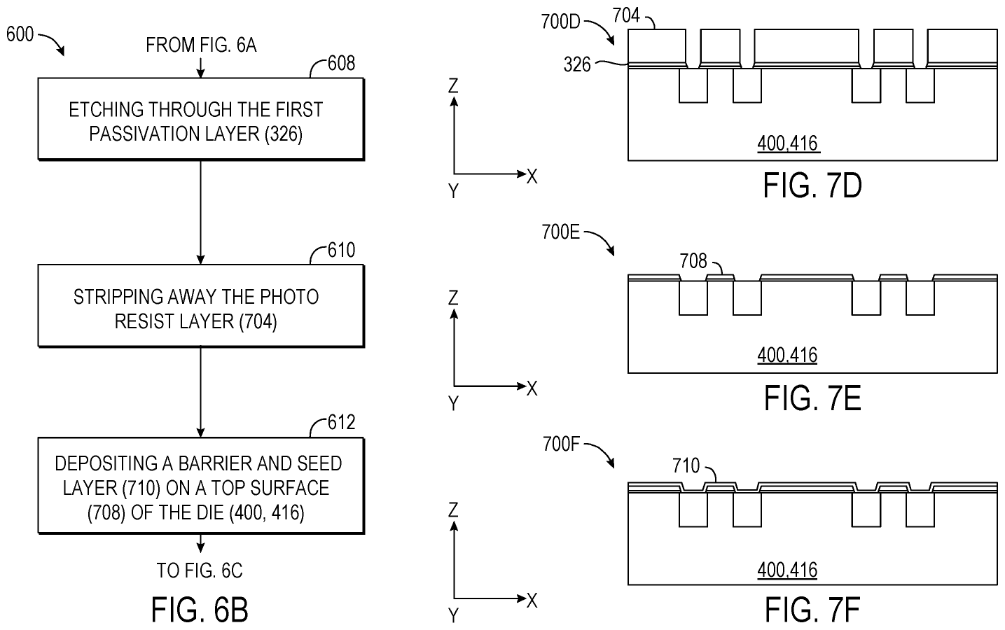

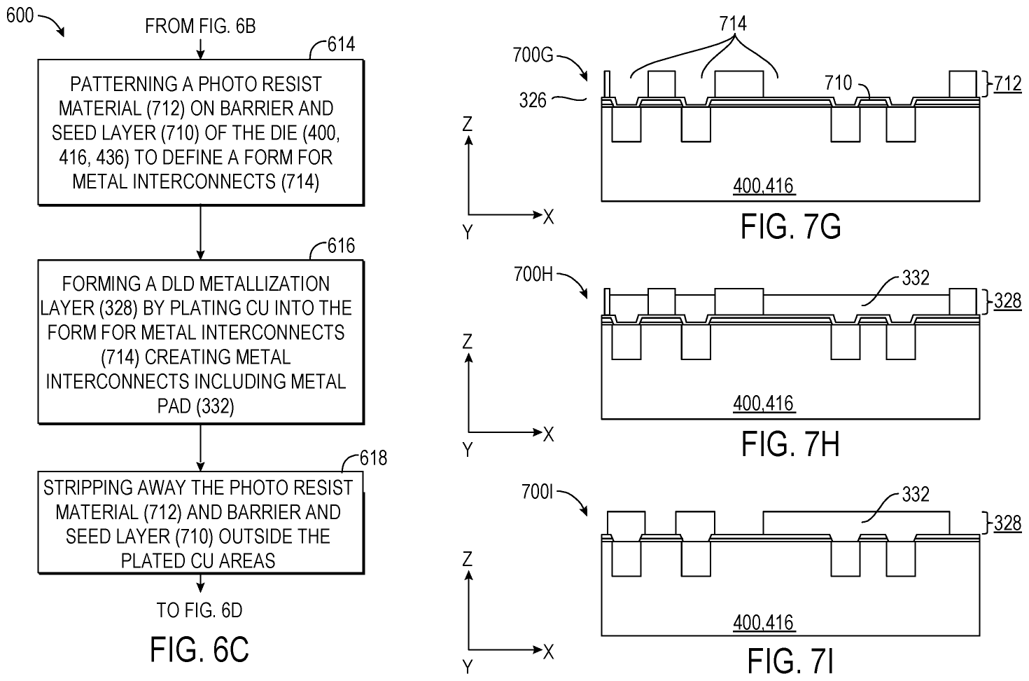

In this example, the IC package 200 includes first and second dies 208(1), 208(2) that are included in respective first and second die packages 212(1), 212(2) that are stacked on top of each other in the vertical direction (Z-axis direction). The first die package 212(1) of the IC package 200 includes the first die 208(1) coupled to the package substrate 203. In this example, the package substrate 203 includes a first, upper and outer metallization layer 214. The first, upper and outer metallization layer 214 provides an electrical interface for signal routing to the first die 208(1). The first die 208(1) is coupled to die interconnects 218 (e.g., raised metal bumps, pillars) that are electrically coupled to metal interconnects 220 in the first, upper and outer metallization layer 214. The first die 208(1) includes the DLD metallization structure 202A which couples the die interconnects 218 to the circuitry within the first die 208(1) and includes a metal pad (not visible) to a metal interconnect (not visible) in the die 208(1) for improved signal path conductivity. The DLD metallization structures 202A-202B will be discussed in more detail in connection with FIGS. 3 and 4A-4F. The metal interconnects 220 in the first, upper metallization layer 214 are coupled to metal vias 222 (not visible) in the package substrate 203, which are coupled to metal interconnects 224 in a second, bottom and outer metallization layer 216. In this manner, the package substrate 203 provides interconnections between its first and second metallization layers 214 and 216 to provide signal routing to the first die 208(1). The first die 208(1) and the second die 208(2) include a metallization structure 202A and 202B, respectively, and will be discussed in more detail in connection with FIGS. 3 and 4A-4F. External interconnects 226 (e.g., ball grid array (BGA) interconnects, a.k.a. bumps) are coupled to the metal interconnects 224 in the second, bottom and outer metallization layer 216 to provide interconnections through the package substrate 203 to the first die 208(1) through the die interconnects 218. In this example, a first, active side 228(1) of the first die 208(1) is adjacent to and coupled to the package substrate 203, and more specifically the first, upper and outer metallization layer 214 of the package substrate 203.

In the exemplary IC package 200 in FIG. 2, an additional optional second die package 212(2) is provided and coupled to the first die package 212(1) to support multiple dies. For example, the first die 208(1) in the first die package 212(1) may include an application processor, and the second die 208(2) may be a memory die, such as a dynamic random access memory (DRAM) die that provides memory support for the application processor. In this regard, in this example, the first die package 212(1) also includes the interposer substrate 204 that is disposed on a package mold 230 encasing the first die 208(1), adjacent to a second, inactive side 228(2) of the first die 208(1). The interposer substrate 204 also includes one or more metallization layers 232 that each include metal interconnects 234 to provide interconnections to the second die 208(2) in the second die package 212(2). The second die package 212(2) is physically and electrically coupled to the first die package 212(1) by being coupled through external interconnects 236 (e.g., solder bumps, BGA interconnects) to the interposer substrate 204. The external interconnects 236 are coupled to the metal interconnects 234 in the interposer substrate 204 through metal vias 238 (not visible). The first die package 212(1) includes vertical interconnects 240 to couple the second die 208(2) to the external interconnects 226 and to the first die 208(1) through the package substrate 203. The second die 208(2) also includes a DLD metallization structure 202B which couples the external interconnects 236 to the circuitry within the second die 208(2) and includes a metal pad and a shorter via coupling the metal pad to a metal interconnect in the second die 208(2) for improved signal path conductivity. The DLD metallization structures 202A-202B will be discussed in more detail in connection with FIGS. 3 and 4A-4F.

FIG. 3 is a side view of an IC 300 that includes a die such as the die 100 of FIG. 1, the die including a DLD metallization structure including a metal pad and a shorter via coupling the metal pad to a metal interconnect in the die for improved signal path conductivity. A die 302 includes a BEOL interconnect structure 304 formed by a BEOL process and disposed on a front-end-of-line (FEOL) structure 306. The FEOL structure 306 includes an active, semiconductor layer 308 that is formed on a substrate 310. The semiconductor layer 308 extends in a first, horizontal direction, which is the X-axis and Y-axis directions as shown in FIG. 3. The semiconductor layer 308 has a first, front side 312F and a second, back side 312B opposite of the first, front side 312F in the second, vertical direction (Z-axis direction). P-type field-effect transistors (FETs) (PFETs) and N-type FETs (NFETs) 314P, 314N are formed in the semiconductor layer 308. The BEOL interconnect structure 304, as a front side interconnect structure 304, is disposed adjacent to the front side 312F of the semiconductor layer 308 in the second, vertical direction (Z-axis direction). The BEOL interconnect structure 304 facilitates signal routing in the die 302 on the front side 312F of the semiconductor layer 308. In this regard, the BEOL interconnect structure 304 includes a plurality of front side, metallization layers 316(1)-316(11) that each include one or more metal interconnects 318(1)-318(11) that can provide direct or indirect interconnections between the FETs 314P, 314N and die interconnects 320 (e.g., a solder bump) adjacent to an upper metallization layer 316(11) of the BEOL interconnect structure 304. The metal interconnects 318(1)-318(11) extend in the first, horizontal direction(s) (X-and/or Y-axis directions). The BEOL interconnect structure 304 also includes via layers 322(1)-322(11) disposed through the front side metallization layers 316(1)-316(11) to provide interconnects between metal interconnects 318(1)-318(11) in adjacent metallization layers 316(1)-316(11).

With continuing reference to FIG. 3, a DLD metallization structure 324 includes the outer metallization layer 316(10) extending in the first, horizontal direction (X-, Y-axes direction). The outer metallization layer 316(10) includes metal interconnect 318(10). The DLD metallization structure 324 also includes a first passivation layer 326 extending in the first, horizontal direction adjacent to the outer metallization layer 316(10). The DLD metallization structure 324 also includes metallization layer 316(11), also referred to as a DLD metallization layer 328, extending in the first, horizontal direction. The DLD metallization layer 328 is a copper layer. The DLD metallization layer 328 is the thickest layer in the die 302, and comprises metal lines, metal traces, and metal pads to mechanically support die interconnects, electrically and physically couple die interconnects to the outer metallization layer 316(10), and distribute signals (power, ground, information) between die interconnects and die interconnects to metal pads in the DLD metallization layer on the periphery of the die 302. The DLD metallization layer 328 has a first surface 330 adjacent to the first passivation layer 326 and a metal pad 332. The DLD metallization structure 324 also includes a first via 334 extending in the second, vertical direction (Z-axis direction) orthogonal to the first direction, the first via 334 coupling the metal pad 332 and the metal interconnect 318(10), the first via 334 having a first height Ht1 in the range between 0.1 μm and 1 μm, inclusively. The first via 334 includes a width, Dw1, such that the aspect ratio Ht1/Dw1 is between 0.06-0.5, inclusively.

The DLD metallization layer 328 has a second surface 336 opposite the first surface 330. The DLD metallization structure 324 also includes a second passivation layer 338 extending in the first, horizontal direction adjacent to the second surface 336 of the DLD metallization layer 328. The first passivation layer 326 and the second passivation layer 338 may consist of either SiN or SiCN without SiO₂ since its purpose is to prevent copper from diffusing into adjacent layers since no polishing process is used to make the die 302.

The die 302 also includes the die interconnect 320 and a second via 340 extending in the second direction orthogonal to the first direction. The second via 340 couples the die interconnect 320 to the metal pad 332 and has a second height, Ht2, in the range between 0.1 μm and 1 μm, inclusively. The second via 340 includes a width, Dw2, such that the aspect ratio Ht2/Dw2 is between 0.06-0.5, inclusively. The die interconnect 320 includes a pillar 342 (e.g., Cu) and an optional solder cap 344.

Dies can be deployed to have various DLD metallization structures. FIGS. 4A-4F address exemplary embodiments of various DLD metallization structures. Each die depicted in FIGS. 4A-4F include an FEOL structure 306 and a BEOL structure 304. For simplicity, FIGS. 4A-4F focus on the DLD metallization structures and, thus, do not depict the FEOL structure 306 and the BEOL structure as they are shown in FIG. 3. Common elements between the die 302 in FIG. 3 and the dies in FIGS. 4A-4F are shown with common element numbers.

FIG. 4A is a side view of an embodiment of a die 400, such as the die 302 in FIG. 3, focusing on an exemplary DLD metallization structure 402 which includes a metal pad 332 and a shorter via 334 coupling the metal pad 332 to a metal interconnect 318(10) in the die 400 for improved signal path conductivity. The DLD metallization structure 402 includes a via 404 having a height, H2, and a width, D2, which is much greater than the height H2. The height H2 can be approximately 0.7 μm. Conductivity is proportional to the surface area of a metal interconnect and inversely proportional to the height of the metal interconnect. By utilizing the thinner second passivation layer 338, a shorter height of the via 404 is advantageously achieved. Additionally, by utilizing the thinner second passivation layer 338, the width of the via 404 may be opened up to this width, D2, to advantageously increase surface area 406, and thus, the conductivity of the via 404 is increased. The width D2 can be in the range between 10 μm and 40 μm. Thus, the aspect ratio of the via 404 can be in the range 0.06 to 0.5, inclusively.

FIG. 4B is a side view of an exemplary IC package 408 including the die 400 in FIG. 4A, rotated 180° and assembled to a substrate 410. The IC package 408 includes the die interconnect 320 soldered to the substrate 410 through a solder 412. The IC package 408 includes an underfill material 414 to further insulate metal interconnects in the DLD metallization layer 328 and insulate the die interconnect 320 from other die interconnects.

FIG. 4C is a side view of another embodiment of a die 416, such as the die 302 in FIG. 3, focusing on an exemplary DLD metallization structure 418 which includes a metal pad 332 and a shorter via 420 coupling the metal pad 332 to the die interconnect 320 in the die 416 for improved signal path conductivity. The die 416 also includes a polymer dielectric layer 422 (e.g. polyimide layer) to insulate the metal interconnects in the DLD metallization layer 328. The via 420 is fabricated utilizing photo imageable material which is removed after the via 420 is formed. In other words, the polymer dielectric layer 422 is not used as a hard etch mask. In so doing, the polymer dielectric layer 422 has a thickness 424 of approximately 4.5 μm. A thickness 426 of the portion of the polymer dielectric layer 422 above a surface 427 in the second vertical direction (Z-axis direction) of the second passivation layer 338 can be in the range between 1-5 μm. The via 420 has a width D3, in a range between 10 μm and 60 μm, inclusively, and a height H3, between 1-5 μm. The DLD metallization structure 418 illustrates the via 420 where the width D3 is defined by a vertical edge 430 of the polymer dielectric layer 422. In other words, the polymer dielectric layer 422 comprises the vertical edge 430 extending in the vertical direction (Z-axis direction) defining a side wall 431 of the via 420.

FIG. 4D is a side view of an exemplary IC package 432 including the die 416 in FIG. 4C rotated 180° and assembled to a substrate 410. The IC package 432 includes the die interconnect 320 soldered to the substrate 410 through a solder 412. The IC package 432 includes an underfill material 434 to further insulate the die interconnect 320 from other die interconnects.

FIG. 4E is a side view of another embodiment of a die 436, such as the die 302 in FIG. 3, focusing on an exemplary DLD metallization structure 438 which includes a metal pad 332 and a shorter via 440 coupling the metal pad 332 to the die interconnect 320 in the die 436 for improved signal path conductivity. The die 436 also includes a polymer dielectric layer 422 to insulate the metal interconnects in the DLD metallization layer 328. The via 440 has side walls in the vertical direction (Z-axis direction) and are defined by vertical edges 442 of the second passivation layer 338 and vertical edge 444 of the polymer dielectric layer 422. The thickness 426 of the portion of the polymer dielectric layer 422 above a surface 446 in the vertical direction (Z-axis direction) of the second passivation layer 338 can be in a range below 1 μm and, preferably 0.7 μm, inclusively. The via 440 has two widths, D4 and D5. The width D4 is defined between the vertical edges 442 of the second passivation layer 338 and is between 10-40 μm, and preferably 20 μm. The width D5 is defined between the vertical edges 444 of the polymer dielectric layer 422 and is between 20-40 μm. The height, H4, of the via 440 is between 1-5 μm, and preferably 3 μm. In other words, the polymer dielectric layer 422 comprises the vertical edges 444 extending in the vertical direction (Z-axis) defining first side walls 445 of the via 440, and the second passivation layer 338 comprises the vertical edges 442 extending in the vertical direction (Z-axis) defining second side walls 447 of the via 440.

FIG. 4F is a side view of an exemplary IC package 448 including the die 436 in FIG. 4E rotated 180° and assembled to a substrate 410. The IC package 448 includes the die interconnect 320 soldered to substrate 410 through a solder 412. The IC package 448 includes an underfill material 434 to insulate the die interconnect 320 from other die interconnects.

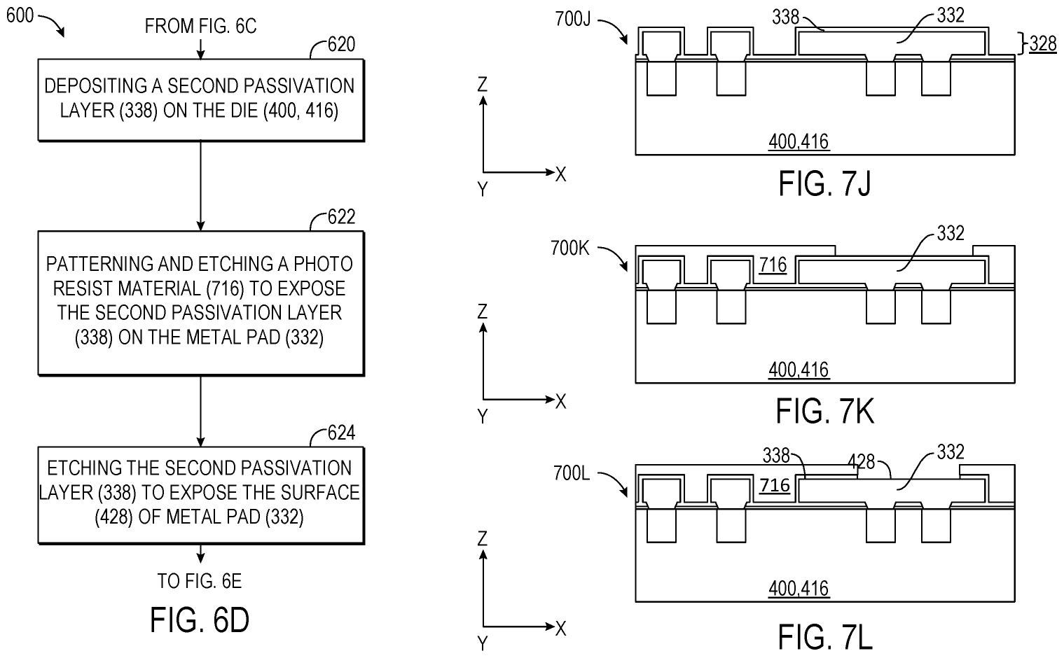

A DLD metallization structure including a metal pad and a shorter via coupling the metal pad to a metal interconnect in a die for improved signal path conductivity, including, but not limited to the exemplary DLD metallization structure 324 in FIG. 3 and the DLD metallization structures 402, 418, and 438 in FIGS. 4A-4F in the related IC package 200 in FIG. 2 can be fabricated by different fabrication processes. FIG. 5 is a flowchart illustrating an exemplary fabrication process 500 of fabricating a DLD metallization structure including a metal pad and a shorter via coupling the metal pad to a metal interconnect in the die for improved signal path conductivity, including, but not limited to, the exemplary DLD metallization structures in FIGS. 3 and 4A-4F.

In this regard, a first exemplary step for fabricating a die with an exemplary DLD metallization structure formed in the die in the fabrication process 500 of FIG. 5 can include fabricating a semiconductor layer 308 extending in a first direction (block 502 in FIG. 5). The next step in the fabrication process 500 can include fabricating a DLD metallization structure 324, 402, 418, 438 (block 504 in FIG. 5). The next step in the fabrication process can include fabricating a BEOL interconnect structure 304 between the semiconductor layer 308 and the DLD metallization structure 324, 402, 418, 438, the BEOL interconnect structure 304 extending in a second direction orthogonal to the first direction (block 506 in FIG. 5). The step of fabricating the DLD metallization structure 324, 402, 418, 438 further comprises blocks 508-514. The next step of fabricating the DLD metallization structure 324, 402, 418, 438 can include fabricating an outer metallization layer 316(10) extending in the first direction, the outer metallization layer 316(10) comprising a metal interconnect 318(10) (block 508 in FIG. 5). The next step of fabricating the DLD metallization structure 324, 402, 418, 438 can include fabricating a first passivation layer 326 extending in the first direction adjacent to the outer metallization layer 316(10) (block 510 in FIG. 5). The next step in the fabrication process 500 can include fabricating a DLD metallization layer 316(11), 328 extending in the first direction, the DLD metallization layer 316(11), 328 comprising a first surface 330 adjacent to the first passivation layer 326 and a metal pad 332 (block 512 in FIG. 5). The next step in the fabrication process can include fabricating a first via 334 extending in the second direction orthogonal to the first direction, the first via 334 coupling the metal pad 332 and the metal interconnect 318(10), the first via 334 having a first aspect ratio between 0.06-0.5, inclusively (block 514 in FIG. 5).

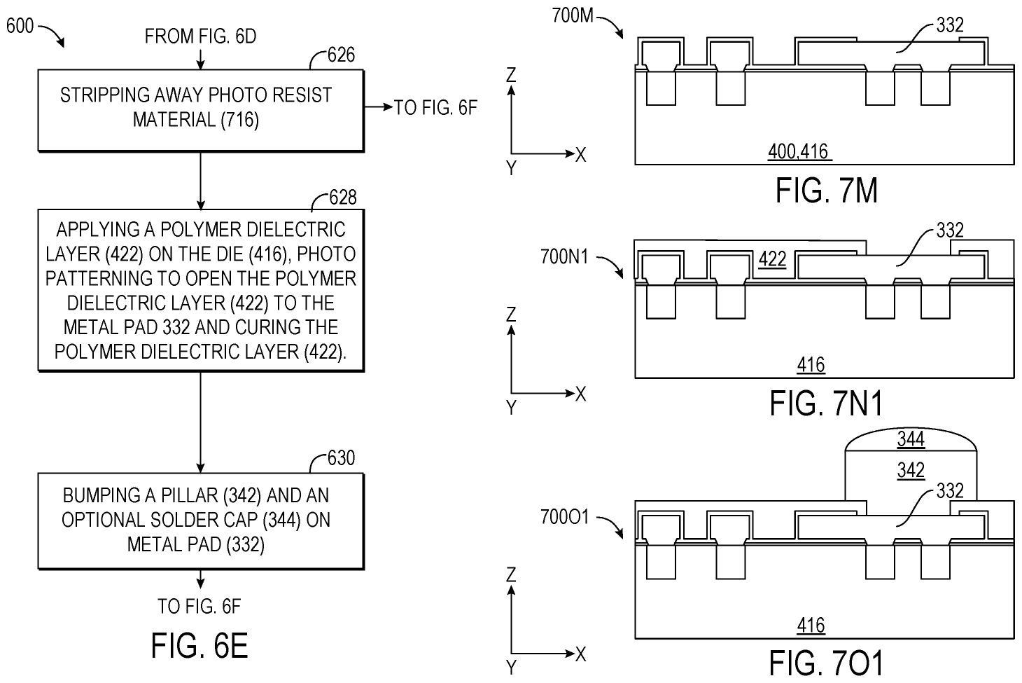

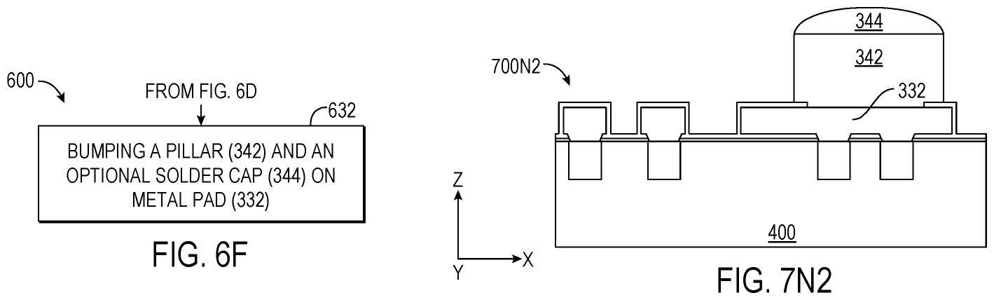

Other fabrication processes can also be employed to fabricate a die having a DLD metallization structure with a metal pad and a shorter via coupling the metal pad to a metal interconnect in the die for improved signal path conductivity, including, but not limited to, the DLD metallization structures 402, 418, and 438 in FIGS. 4A-4F in the related IC package 200 in FIG. 2. In this regard, FIGS. 6A-6F is a flowchart illustrating another exemplary fabrication process of fabricating a die having a DLD metallization structure with a metal pad and a shorter via coupling the metal pad to a metal interconnect in the die for improved signal path conductivity including, but not limited to, the DLD metallization structures 402, 418, and 438 in FIGS. 4A-4F. FIGS. 7A-7O1 and 7N2 are exemplary fabrication stages 700A-700O1 and 700N2 during fabrication of the DLD metallization structure according to the fabrication process in FIGS. 6A-6F. The fabrication process 600 as shown in the fabrication stages 700A-700O1 and 700N2 in FIGS. 7A-7O1 and 7N2 are in reference to the cross-sectional side view of a die and, thus, will be discussed with reference to the dies 400, 416 in FIGS. 4A and 4C which are deployed, such as the die 108(1), in the related IC package 200 in FIG. 2. In particular blocks 502-530 relate to the die 416 and blocks 502-526 and 532 relate to the die 400. For simplicity, the fabrication process 600 will be focused on the DLD metallization structure fabricated therein.

In this regard, as shown in fabrication stage 700A in FIG. 7A, an exemplary step in the fabrication process 600 is providing a die 400, 416 with a semiconductor layer (not visible) and a BEOL structure including an outer metallization layer 316(10) which is fabricated in the die 400, 416 with an etch stop layer 702 (block 602 in FIG. 6A). Although not shown in the fabrication stages for simplicity, the fabrication stages address a wafer level fabrication process where the die 400, 416 is one of many dies disposed in a wafer. The die would be fabricated in a wafer (not shown) in a wafer level fabrication process. As shown in fabrication stage 700B in FIG. 7B, a next step in the fabrication process 600 can include depositing a first passivation layer 326 on the etch stop layer 702 (block 604 in FIG. 6A). As shown in fabrication stage 700C in FIG. 7C, a next step in the fabrication process 600 can include patterning a photo resist material 704 over metal interconnects 706A-706D in the outer metallization layer 316(10) (block 606 in FIG. 6A).

As shown in fabrication stage 700D in FIG. 7D, a next step in the fabrication process 600 can include etching through the first passivation layer 326 (block 608 in FIG. 6B). As shown in fabrication stage 700E in FIG. 7E, a next step in the fabrication process 600 can include stripping away the photo resist material 704 (block 610 in FIG. 6B). As shown in fabrication stage 700F in FIG. 7F, a next step in the fabrication process 600 can include depositing a barrier and seed layer 710 on a top surface 708 of the die 400, 416 (block 612 in FIG. 6B).

As shown in fabrication stage 700G in FIG. 7G, a next step in the fabrication process 600 can include patterning a photo resist material 712 on the barrier and seed layer 710 of the die 400, 416 to define a form for metal interconnects 714 (block 614 in FIG. 6C). As shown in fabrication stage 700H in FIG. 7H, a next step in the fabrication process 600 can include forming a DLD metallization layer 328 by plating Cu into the form for the metal interconnects 714 creating metal interconnects including metal pad 332 (block 616 in FIG. 6C). As shown in fabrication stage 700I in FIG. 7I, a next step in the fabrication process 600 can include stripping away the photo resist material 712 and the barrier and seed layer 710 outside the plated Cu areas (block 618 in FIG. 6C). Please note that for simplicity the barrier and seed layer 710 in the plated Cu areas such as metal pad 332 is no longer delineated and are considered part of the metal pad 332.

Recognizing that the die 400, 416 will not be assembled with another die through a Cu—Cu hybrid bonding process, a subsequent polishing step to polish the surface of the DLD metallization layer 328 will not be used. As a result, additional margin material in a passivation layer is not needed. As such, as shown in fabrication stage 700J in FIG. 7J, a next step in the fabrication process 600 can include depositing a second passivation layer 338 on the die 400, 416 (block 620 in FIG. 6D). As shown in fabrication stage 700K in FIG. 7K, a next step in the fabrication process 600 can include patterning and etching a photo resist material 716 to expose the second passivation layer 338 on the metal pad 332 (block 622 in FIG. 6D). As shown in fabrication stage 700L in FIG. 7L, a next step in the fabrication process 600 can include etching the second passivation layer 338 to expose the surface 428 of the metal pad 332 (block 624 in FIG. 6D). This step of the process 600 can be tailored to etch the surface 428 of the metal pad 332 so that the vertical edges of the photo resist material 716 coincide with the vertical edge of the second passivation layer 338 as shown on the die 416 in FIG. 4C.

As shown in fabrication stage 700M in FIG. 7M, a next step in the fabrication process 600 can include stripping away the photo resist material 716 (block 626 in FIG. 6E). If the die 400 is being fabricated, the process 600 proceeds to block 732 in FIG. 6F). Continuing with fabricating the die 416, the process 600 proceeds to block 628 in FIG. 6N1. As shown in fabrication stage 700N1 in FIG. 7N1, a next step in the fabrication process 600 can include applying a polymer dielectric 422 (i.e. polymer dielectric) on the die 416, photo patterning to open the polymer dielectric layer 422 to the metal pad 332 and curing the polymer dielectric layer 422 (block 628 in FIG. 6E). As shown in fabrication stage 700O1 in FIG. 7O1, a next step in the fabrication process 600 can include bumping a pillar 342 and an optional solder cap 344 on the metal pad 332 (block 630 in FIG. 6E).

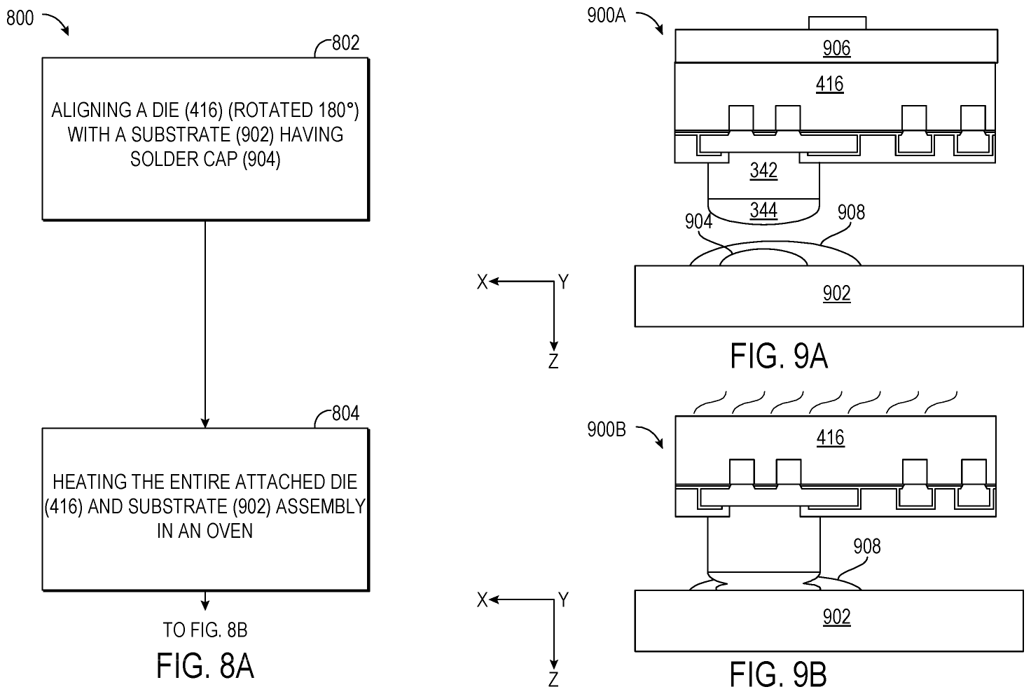

Returning to block 626 in FIG. 6E, the process 600 proceeds to block 632 of FIG. 6F to continue fabrication of the die 400. As shown in fabrication stage 700N2 in FIG. 7N2, a next step in the fabrication process 600 can include bumping a pillar 342 and an optional solder cap 344 on the metal pad 332 without depositing a polymer dielectric layer (block 632 in FIG. 6F). At the end of the wafer level fabrication process 700, the dies disposed on a wafer including die 400, 417 are singulated from the wafer and sent to an assembly process such as the assembly processes that will be discussed in connection with FIGS. 8-11.

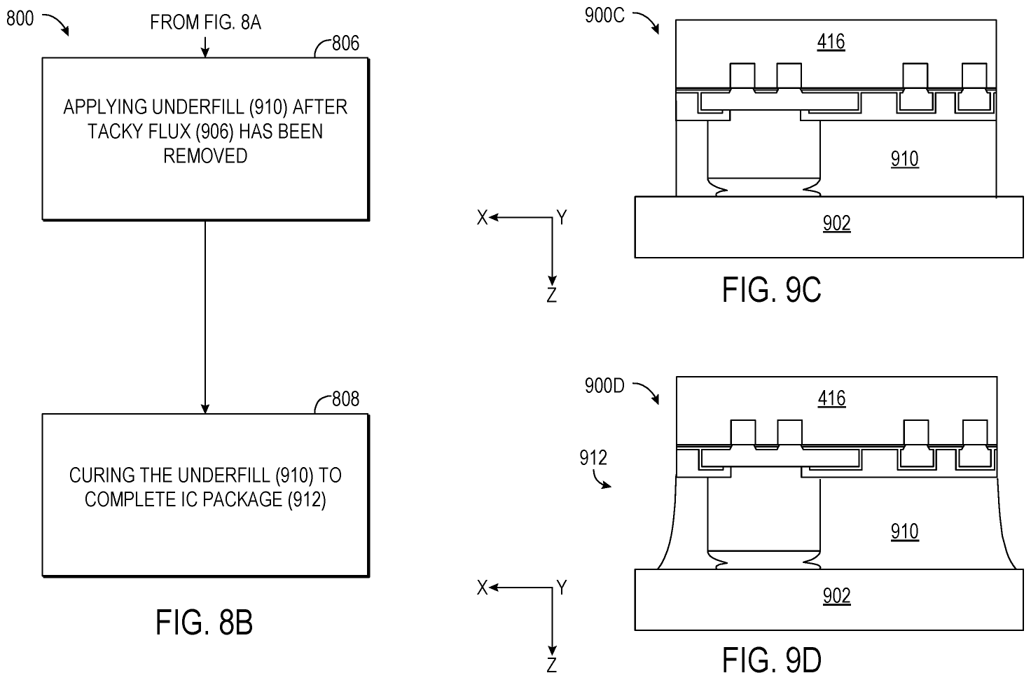

An IC package including a die having a DLD metallization structure wherein the DLD metallization structure includes a metal pad and a shorter via coupling the metal pad to a metal interconnect in a die for improved signal path conductivity, including, but not limited to the exemplary 3DIC package 200 in FIG. 2 and the DLD metallization structures 402, 418, and 438 in FIGS. 4A-4F in the related IC package 200 in FIG. 2 can be assembled by different assembly processes. FIGS. 8A-8B is a flowchart illustrating an exemplary mass reflow assembly process 800 of assembling a die to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 4A-4F. FIGS. 9A-9D are exemplary assembly stages for assembling the die to the substrate according to the assembly process 800 in FIGS. 8A-8B. The assembly process 800 may be applied to dies with a polymer dielectric layer such as polymer dielectric layer 422 in dies 416, and 436 but will be described in relation to the die 416.

In this regard, as shown in assembly stage 900A in FIG. 9A, an exemplary step in the assembly process 800 can include aligning a die 416 (rotated 180°) with a substrate 902 having an optional bump landing pad 904 (block 802 in FIG. 8A). The die 416 is placed on a carrier 906 to align the die 400 with the substrate 902. The bump landing pad 904 is covered with a tacky flux 908. The tacky flux 908 facilitates placing the die 416 on the substrate 902 with minor force.

As shown in assembly stage 900B in FIG. 9B, a next step in the assembly process 800 can include heating the entire attached die 416 and substrate 902 assembly in an oven (block 804 in FIG. 8A). As shown in assembly stage 900C in FIG. 9C, a next step in the assembly process 800 can include applying an underfill 910 after the tacky flux 908 has been removed (block 806 in FIG. 8B). As shown in assembly stage 900D in FIG. 9D, a next step in the assembly process 800 can include curing the underfill 910 to complete IC package 912 (block 808 in FIG. 8B).

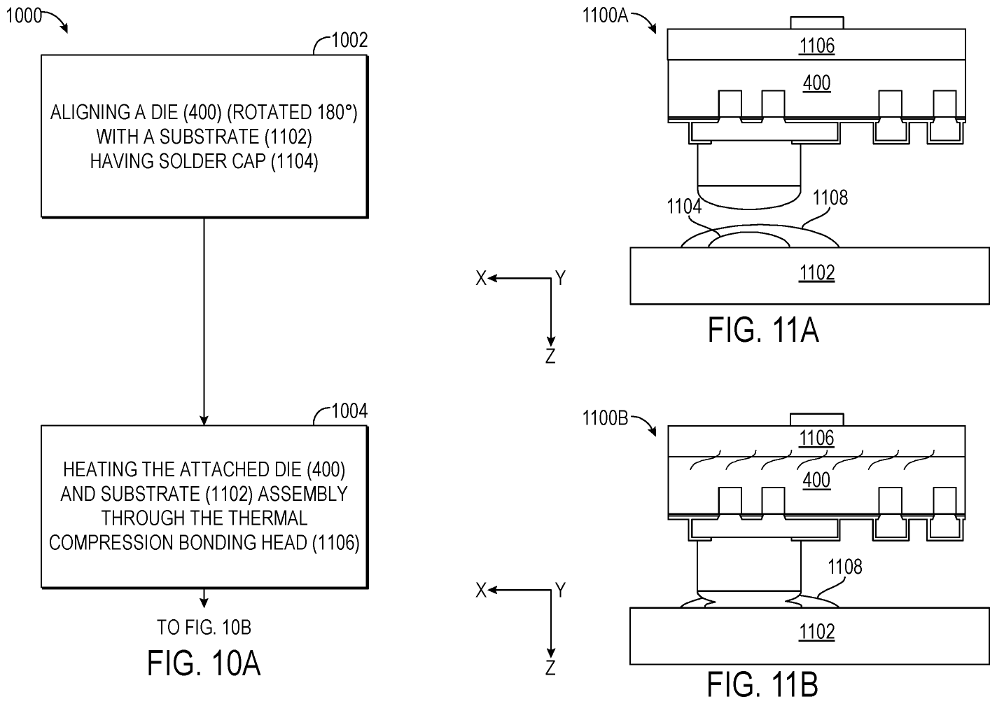

FIGS. 10A-10B is a flowchart illustrating an exemplary thermal compression assembly process 1000 of assembling a die to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 4A-4F. The assembly process 1000 may be applied to dies with or without a polymer dielectric layer such as polymer dielectric layer 422 and will be described in relation to the die 400.

The assembly process 1000 may be applied to the dies 400, 416, and 436 but will be described in relation to the die 400.

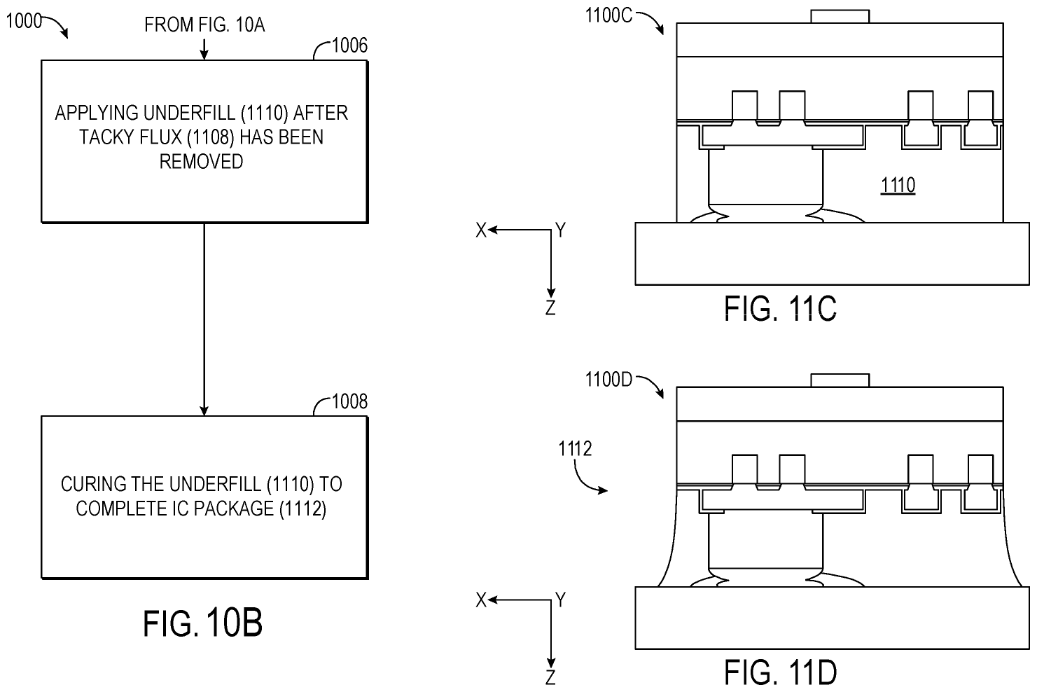

In this regard, as shown in assembly stage 1100A in FIG. 11A, an exemplary step in the assembly process 1000 can include aligning a die 400 (rotated 180°) with a substrate 1102 having a solder cap 1104 (block 1002 in FIG. 10A). The die 400 is placed on a thermal compression bonding head 1106 to align the die 400 with the substrate 1102. The solder cap 1104 is covered with a tacky flux 1108. The tacky flux 1108 facilitates placing the die 400 on the substrate 1102 with minor force. As shown in assembly stage 1100B in FIG. 11B, a next step in the assembly process 1000 can include heating the attached die 400 and substrate 1102 assembly through the thermal compression bonding head 1106 (block 1004 in FIG. 10A). As shown in assembly stage 1100C in FIG. 11C, a next step in the assembly process 1000 can include applying an underfill 1110 after the tacky flux 1108 has been removed. (block 1006 in FIG. 10B). As shown in assembly stage 1100D in FIG. 11D, a next step in the assembly process 1000 can include curing the underfill 1110 to complete IC package 1112. (block 1008 in FIG. 10B).

Electronic devices that include an IC package, wherein the IC package includes a die attached to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 4A-4F in the related IC package 200 in FIG. 2, and that can be fabricated according to, but not limited to, the exemplary fabrication processes in FIGS. 5 and 6A-6F, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

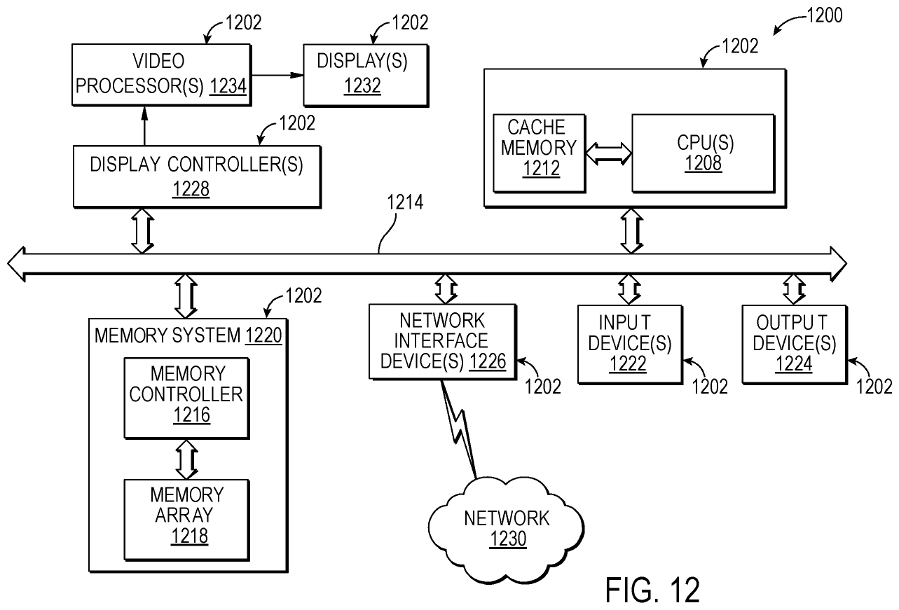

In this regard, FIG. 12 is a block diagram of an exemplary processor-based system that can include components deployed in an IC package employing a die(s) coupled to a package substrate, wherein the die(s) can include a DLD metallization structure including a metal pad and a shorter via coupling the metal pad to a metal interconnect in the die for improved signal path conductivity, including, but not limited to, the exemplary DLD metallization structures in FIGS. 3 and 4A-4F, according to the exemplary fabrication processes in FIG. 5 and FIGS. 6A-6F, and according to exemplary assembly processes in FIGS. 8A-8B and 10A-10B, and according to any exemplary aspects disclosed herein. In this example, the processor-based system 1200 may be formed as an IC package 1202 such as the IC package 200 in FIG. 2. The processor-based system 1200 includes a central processing unit (CPU) 1208 that includes one or more processors 1210, which may also be referred to as CPU cores or processor cores. The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216, as an example of a slave device. Although not illustrated in FIG. 7, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. Each of the memory system(s) 1220, the one or more input devices 1222, the one or more output devices 1224, the one or more network interface devices 1226, and the one or more display controllers 1228 can be provided in the same or different electronic devices. The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display controller(s) 1228 sends information to the display(s) 1232 to be displayed via one or more video processor(s) 1234, which process the information to be displayed into a format suitable for the display(s) 1232. The display controller(s) 1228 and video processor(s) 1234 can be included as ICs in the same or different electronic devices, and in the same or different electronic devices containing the CPU 1208, as an example. The display(s) 1232 can include any type of display, including, but not limited to, a cathode ray tube (CRT), a liquid crystal display (LCD), a plasma display, a light emitting diode (LED) display, etc.

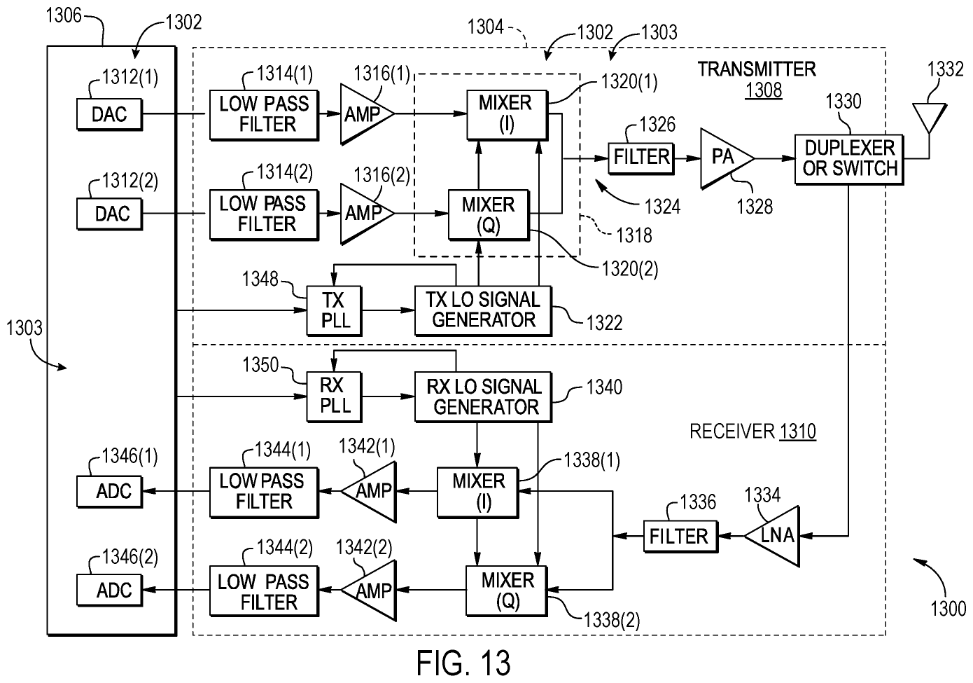

FIG. 13 is a block diagram of an exemplary wireless communications device that includes radio-frequency (RF) components deployed in an IC package, wherein the IC package includes a DLD metallization structure including a metal pad and a shorter via coupling the metal pad to a metal interconnect in the die for improved signal path conductivity, including, but not limited to, the exemplary DLD metallization structures in FIGS. 3 and 4A-4F, according to the exemplary fabrication processes in FIG. 5 and FIGS. 6A-6F, and according to exemplary assembly processes in FIGS. 8A-8B and 10A-10B, and according to any exemplary aspects disclosed herein. The wireless communications device 1300 may include or be provided in any of the above-referenced devices, as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals (e.g., I and Q output currents) for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency up-conversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Down-conversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency up-conversion, while the RX LO signal generator 1340 generates the I and Q RX LO signals used for frequency down-conversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A semiconductor die (die), comprising:
   a semiconductor layer extending in a first direction;
   a die level distribution (DLD) metallization structure; and
   a back end of line (BEOL) interconnect structure between the semiconductor layer and the DLD metallization structure, the BEOL interconnect structure extending in a second direction orthogonal to the first direction;
   the DLD metallization structure comprising:
      an outer metallization layer extending in the first direction, the outer metallization layer comprising a metal interconnect;
      a first passivation layer extending in the first direction adjacent to the outer metallization layer;
      a DLD metallization layer extending in the first direction, the DLD metallization layer comprising:
         a first surface adjacent to the first passivation layer; and
         a metal pad; and
      a first via extending in the second direction orthogonal to the first direction, the first via coupling the metal pad and the metal interconnect, the first via having a first aspect ratio between 0.06-0.5, inclusively.
2. The semiconductor die of clause 1, wherein
   the DLD metallization layer further comprises a second surface opposite the first surface; and
   the DLD metallization structure further comprises:
      a second passivation layer extending in the first direction adjacent to the second surface of the DLD metallization layer.
3. The semiconductor die of clause 2, further comprising:
   a first die interconnect; and
   a second via extending in the second direction orthogonal to the first direction, the second via coupling the first die interconnect to the metal pad, the second via having a second aspect ratio between 0.06-0.5, inclusively.
4. The semiconductor die of any of clauses 1-3, wherein the first passivation layer consists of silicon nitride (SiN).
5. The semiconductor die of any of clauses 1-4, wherein the second passivation layer consists of silicon nitride (SiN).
6. The semiconductor die of any of clauses 3-5, further comprising:
   a substrate, the first die interconnect coupled to the substrate; and
   an underfill between the second passivation layer and the substrate.
7. The semiconductor die of any of clauses 2-6, further comprising:
   a polymer dielectric layer extending in the first direction adjacent to the second passivation layer;
   a second die interconnect; and
   a third via extending in the second direction orthogonal to the first direction, the third via coupling the second die interconnect to the metal pad.
8. The semiconductor die of clause 7, further comprising:
   a substrate, the second die interconnect coupled to the substrate; and
   an underfill between the polymer dielectric layer and the substrate.
9. The semiconductor die of clause 7 or 8, wherein the polymer dielectric layer comprises a first edge extending in the second direction defining a side wall of the third via
10. The semiconductor die of any of clauses 7-9, wherein:
   the polymer dielectric layer comprises a first edge extending in the second direction defining a first side wall of the third via; and
   the second passivation layer comprises a second edge extending in the second direction defining a second side wall of the third via.
11. The semiconductor die of any of clauses 1-10 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.
12. A method of fabricating a semiconductor die (die) for improved signal path conductivity, comprising:
   fabricating a semiconductor layer extending in a first direction;
   fabricating a die level distribution (DLD) metallization structure; and
   fabricating a back end of line (BEOL) interconnect structure between the semiconductor layer and the DLD metallization structure, the BEOL interconnect structure extending in a second direction orthogonal to the first direction;
   wherein fabricating the DLD metallization structure comprises:
      fabricating an outer metallization layer extending in the first direction, the outer metallization layer comprising a metal interconnect;
      fabricating a first passivation layer extending in the first direction adjacent to the outer metallization layer;
      fabricating a DLD metallization layer extending in the first direction, the DLD metallization layer comprising:
         a first surface adjacent to the first passivation layer; and
         a metal pad; and
      fabricating a first via extending in the second direction orthogonal to the first direction, the first via coupling the metal pad and the metal interconnect, the first via having a first aspect ratio between 0.06-0.5, inclusively.
13. The method of clause 12, wherein:
   the DLD metallization layer comprises a second surface opposite the first surface; and
   fabricating the DLD metallization structure further comprises:
      fabricating a second passivation layer extending in the first direction adjacent to the second surface of the DLD metallization layer.
14. The method of clause 13, further comprising:
   fabricating a first die interconnect; and
   fabricating a second via extending in the second direction orthogonal to the first direction, the second via coupling the first die interconnect to the metal pad, the second via having a second aspect ratio between 0.06-0.5, inclusively.
15. The method of any of clauses 12-14, wherein the first passivation layer consists of silicon nitride (SiN).
16. The method of any of clauses 12-15, wherein the second passivation layer consists of silicon nitride (SiN).
17. The method of any of clauses 14-16, further comprising: providing a substrate, the first die interconnect coupled to the substrate; and depositing an underfill between the second passivation layer and the substrate.
18. The method of any of clauses 13-17, further comprising:
   depositing a polymer dielectric layer extending in the first direction adjacent to the second passivation layer;
   fabricating a second die interconnect; and
   fabricating a third via extending in the second direction orthogonal to the first direction, the third via coupling the second die interconnect to the metal pad.
19. The method of clause 18, further comprising:
   providing a substrate, the second die interconnect coupled to the substrate; and
   depositing an underfill between the polymer dielectric layer and the substrate.
20. The method of clause 18 or 19, wherein the polymer dielectric layer comprises a first edge extending in the second direction defining a side wall of the third via.

What is claimed is:

1. A semiconductor die (die), comprising:
a semiconductor layer extending in a first direction;
a die level distribution (DLD) metallization structure; and
a back end of line (BEOL) interconnect structure between the semiconductor layer and the DLD metallization structure, the BEOL interconnect structure extending in a second direction orthogonal to the first direction;
the DLD metallization structure comprising:
an outer metallization layer extending in the first direction, the outer metallization layer comprising a metal interconnect;
a first passivation layer extending in the first direction adjacent to the outer metallization layer;
a DLD metallization layer extending in the first direction, the DLD metallization layer comprising:
a first surface adjacent to the first passivation layer; and
a metal pad; and
a first via extending in the second direction orthogonal to the first direction, the first via coupling the metal pad and the metal interconnect, the first via having a first aspect ratio between 0.06-0.5, inclusively.

2. The semiconductor die of claim 1, wherein
the DLD metallization layer further comprises a second surface opposite the first surface; and
the DLD metallization structure further comprises:
a second passivation layer extending in the first direction adjacent to the second surface of the DLD metallization layer.

3. The semiconductor die of claim 2, further comprising:
a first die interconnect; and
a second via extending in the second direction orthogonal to the first direction, the second via coupling the first die interconnect to the metal pad, the second via having a second aspect ratio between 0.06-0.5, inclusively.

4. The semiconductor die of claim 1, wherein the first passivation layer consists of silicon nitride (SiN).

5. The semiconductor die of claim 2, wherein the second passivation layer consists of silicon nitride (SiN).

6. The semiconductor die of claim 3, further comprising:
a substrate, the first die interconnect coupled to the substrate; and
an underfill between the second passivation layer and the substrate.

7. The semiconductor die of claim 2, further comprising:
a polymer dielectric layer extending in the first direction adjacent to the second passivation layer;
a second die interconnect; and
a third via extending in the second direction orthogonal to the first direction, the third via coupling the second die interconnect to the metal pad.

8. The semiconductor die of claim 7, further comprising:
a substrate, the second die interconnect coupled to the substrate; and
an underfill between the polymer dielectric layer and the substrate.

9. The semiconductor die of claim 7, wherein the polymer dielectric layer comprises a first edge extending in the second direction defining a side wall of the third via.

10. The semiconductor die of claim 7, wherein:
the polymer dielectric layer comprises a first edge extending in the second direction defining a first side wall of the third via; and
the second passivation layer comprises a second edge extending in the second direction defining a second side wall of the third via.

11. The semiconductor die of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.

12. A method of fabricating a semiconductor die (die) for improved signal path conductivity, comprising:
fabricating a semiconductor layer extending in a first direction;
fabricating a die level distribution (DLD) metallization structure; and
fabricating a back end of line (BEOL) interconnect structure between the semiconductor layer and the DLD metallization structure, the BEOL interconnect structure extending in a second direction orthogonal to the first direction;
wherein fabricating the DLD metallization structure comprises:
fabricating an outer metallization layer extending in the first direction, the outer metallization layer comprising a metal interconnect;
fabricating a first passivation layer extending in the first direction adjacent to the outer metallization layer;
fabricating a DLD metallization layer extending in the first direction, the DLD metallization layer comprising:
a first surface adjacent to the first passivation layer; and
a metal pad; and
fabricating a first via extending in the second direction orthogonal to the first direction, the first via coupling the metal pad and the metal interconnect, the first via having a first aspect ratio between 0.06-0.5, inclusively.

13. The method of claim 12, wherein:
the DLD metallization layer comprises a second surface opposite the first surface; and
fabricating the DLD metallization structure further comprises:
fabricating a second passivation layer extending in the first direction adjacent to the second surface of the DLD metallization layer.

14. The method of claim 13, further comprising:
fabricating a first die interconnect; and
fabricating a second via extending in the second direction orthogonal to the first direction, the second via coupling the first die interconnect to the metal pad, the second via having a second aspect ratio between 0.06-0.5, inclusively.

15. The method of claim 12, wherein the first passivation layer consists of silicon nitride (SiN).

16. The method of claim 13, wherein the second passivation layer consists of silicon nitride (SiN).

17. The method of claim 14, further comprising:
providing a substrate, the first die interconnect coupled to the substrate; and
depositing an underfill between the second passivation layer and the substrate.

18. The method of claim 13, further comprising:
depositing a polymer dielectric layer extending in the first direction adjacent to the second passivation layer;
fabricating a second die interconnect; and
fabricating a third via extending in the second direction orthogonal to the first direction, the third via coupling the second die interconnect to the metal pad.

19. The method of claim 18, further comprising:
providing a substrate, the second die interconnect coupled to the substrate; and
depositing an underfill between the polymer dielectric layer and the substrate.

20. The method of claim 18, wherein the polymer dielectric layer comprises a first edge extending in the second direction defining a side wall of the third via.
